(19) United States
(12) Patent Application Publication
(10) Pub. No.: US 2025/0132279 A1
(43) Pub. Date: Apr. 24, 2025

(54) NON-CONDUCTIVE FILM FILLET CONTROL IN SEMICONDUCTOR DEVICE ASSEMBLY

(71) Applicant: Micron Technology, Inc., Boise, ID (US)

(72) Inventors: Brandon P. Wirz, Boise, ID (US); Andrew M. Bayless, Boise, ID (US); Owen R. Fay, Meridian, ID (US)

(21) Appl. No.: 18/790,320

(22) Filed: Jul. 31, 2024

Related U.S. Application Data
(60) Provisional application No. 63/544,921, filed on Oct. 19, 2023.

(51) Int. Cl. H01L 23/00

(52) U.S. Cl. CPC H01L 24/29; H01L 24/32; H01L 24/83; H01L 24/16; H01L 24/73; H01L 2224/16145; H01L 2224/26145; H01L 2224/32145; H01L 2224/73204; H01L 2224/83007

(57) ABSTRACT

A semiconductor device is presented. The semiconductor device includes a lower semiconductor die, a stack of upper semiconductor dies disposed over the lower semiconductor die, a non-conductive film material disposed between adjacent semiconductor dies of the lower semiconductor die and the stack of upper semiconductor dies, and an epoxy material disposed on at least one sidewall of the stack of upper semiconductor dies, wherein the epoxy material has a different material composition to the NCF material.

### CROSS-REFERENCE TO RELATED APPLICATION(S)

The present application claims priority to U.S. Provisional Patent Application No. 63/544,921, filed Oct. 19, 2023, the disclosure of which is incorporated herein by reference in its entirety.

### TECHNICAL FIELD

The present disclosure generally relates to semiconductor devices, and more particularly relates to control of non-conductive film (NCF) fillet in semiconductor device assembly.

### BACKGROUND

Semiconductor packages typically include a semiconductor die (e.g., memory chip, microprocessor chip, imager chip) mounted on a substrate or an interposer and encased in a protective covering (e.g., an encapsulating material). The semiconductor die may include functional features, such as memory cells, processor circuits, or imager devices, as well as bond pads electrically connected to the functional features. The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies for advanced semiconductor device packaging (e.g., high bandwidth memory (HBM) devices).

### BRIEF DESCRIPTION OF THE DRAWINGS

FIG. 1 depicts a cross sectional view of a semiconductor device assembly.

FIG. 2 depicts a cross sectional view of another semiconductor device assembly in accordance with embodiments of the present technology.

FIGS. 3A through 3C illustrate stages of forming semiconductor dies for semiconductor device assembly in accordance with embodiments of the present technology.

FIG. 4 illustrates a stage of stacking semiconductor dies in accordance with embodiments of the present technology.

FIG. 5 illustrates a stage of forming epoxy layers on sidewalls of semiconductor device assembly in accordance with embodiments of the present technology.

FIG. 6 illustrates a stage of curing treatment on deposited epoxy layers of semiconductor device assembly in accordance with embodiments of the present technology.

FIG. 7 shows a top-down view of the semiconductor device assembly of FIG. 6 in accordance with embodiments of the present technology.

FIG. 8 illustrates a stage of NCF material extending outside the semiconductor dies of the semiconductor device assembly in accordance with embodiments of the present technology.

FIG. 9 is a flow chart illustrating a method of processing semiconductor device assemblies with epoxy material in accordance with embodiments of the present technology.

FIG. 10 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

CoW assembly is a promising technology for advanced semiconductor device packaging applications. It can be used to overcome the limitations of Wafer-to-Wafer (WoW) bonding and improve die stacking process yield and bonding placement accuracy. CoW assembly can also be adopted for a higher semiconductor device density with reduced package size. For example, in HBM device fabrication, multiple memory dies (e.g., 4, 8, 16, or 32) can be stacked on top of an interposer die which serves as a communication bridge between the memory dies and a processor. HBM device with stacked memory dies can provide significant higher bandwidth and energy efficiency compared to traditional memory solutions.

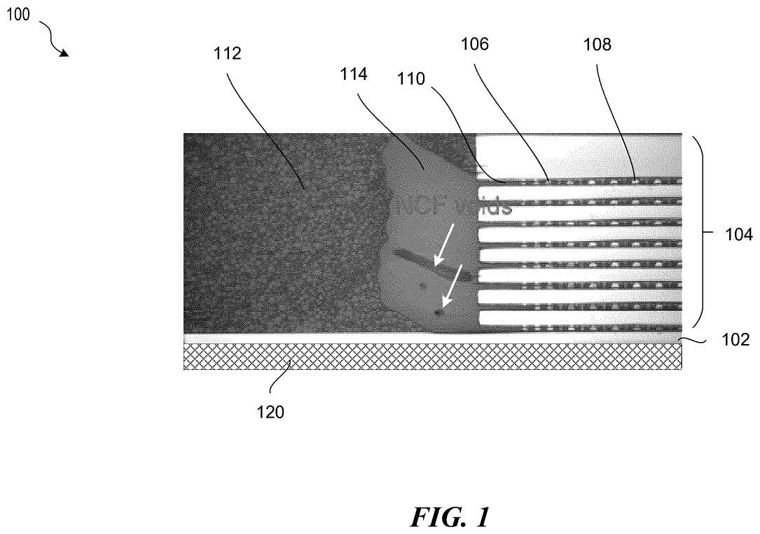

During the CoW semiconductor device assembly, a thermal compression bonding (TCB) process is generally applied to stack multiple semiconductor dies (e.g., memory dies) on a logic wafer or a substrate. The TCB process modifies the profile and location of NCF material in the semiconductor device assembly and may cause severe defects and reliability issues. For example, FIG. 1 depicts a cross sectional view of a semiconductor device assembly 100 which includes a plurality of memory dies 104 vertically stacked on an interposer (IF) wafer 102. Each one of the plurality of memory dies 104 and the IF wafer 102 can be interconnected through solder balls 108 and contact pads 106. NCF material 110 is disposed between adjacent memory dies 104 for electrical isolation and to provide mechanical support. The semiconductor device assembly is further encapsulated by encapsulating material 112 and/or packaging material 120.

In the semiconductor device assembly 100, the plurality of memory dies 104 are bonded onto each other and on the IF wafer 102 through the TCB process. The TCB process involves applying heat and pressure to bond the memory dies 104 to the IF wafer 102, typically using a controlled working environment and specialized processing tools. Specifically, heat and pressure can be applied simultaneously to the memory dies 104 and the IF wafer 102. During the TCB process, the heat applied can melt the metal layers of the contact pads 106, and the pressure applied can facilitate a formation of strong metal-to-metal bonds between the contact pads 106 and corresponding solder balls 108. The pressure helps to ensure good electrical contact and reliable mechanical bonding between adjacent memory dies 104 and IF wafer 102.

The TCB process, however, may cause the NCF fillets 114 that squeeze out of the memory dies 104 packaging area. For example, as shown in FIG. 1, a portion of NCF material 110 squeezes out a sidewall of the stack of memory dies 104 and form NCF fillets 114. Further, the squeezed NCF fillets 114 can combine and form voids. The squeezing of NCF material 110 outside the packaging area of memory dies 104 is related to the heat and pressure applied during the TCB process. A high bonding temperature and/or a high pressure applied in the TCB process will enhance the flowing of NCF material and push NCF material outside the memory dies 104 packaging area. The squeezed NCF fillets and NCF voids can be a big concern in advanced semiconductor device packaging, e.g., HBM device packages. For example, in a CoW assembly for packaging a HBM device, the squeezed NCF material can connect between packages, therefore changing the wafer warpage and causing processing issues. In addition, NCF fillets 114 having a large size can also contaminate bond tips and cause manufacturing defects and device reliability issues. Further, exposed NCF and NCF voids at the package edge can cause reliability issues due to exposed interconnects. Even though an incoming NCF layer thickness can be reduced to help control the extending, a thinner layer of NCF and narrow gaps between adjacent semiconductor dies may cause NCF voids in the package. Further, the NCF material may not cover corner areas of the semiconductor device assembly with a reduced thickness, leading to another reliability issue.

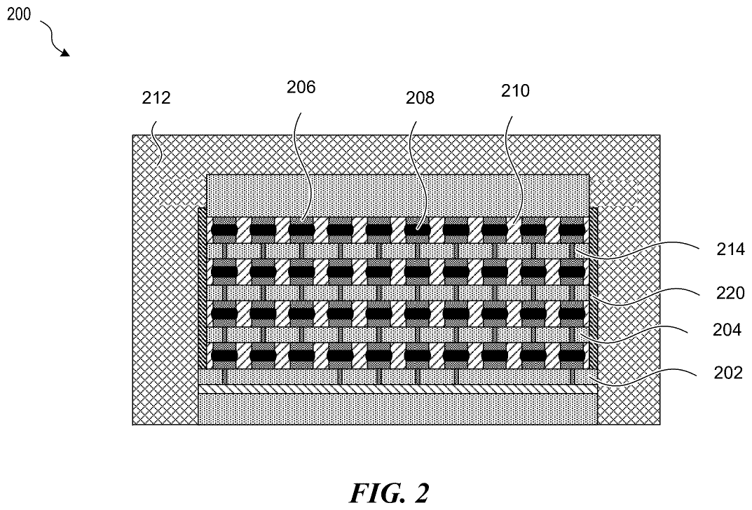

The present technology utilizes epoxy material to prevent NCF fillet squeezing out of packaging area of stacked semiconductor dies. Specifically, an epoxy layer can be applied at a center region of each of the sidewalls of stacked semiconductor dies and configured as a barrier layer to stop diffusion of NCF material during a TCB process. Furthermore, to prevent NCF non-coverage at corner of semiconductor device packages, the NCF material can be squeezed out the semiconductor packaging region, e.g., corner regions, where no epoxy material exists. FIG. 2 depicts a cross sectional view of another semiconductor device assembly 200 in accordance with embodiments of the present technology. In this example, multiple semiconductor dies can be vertically stacked above a substrate or another semiconductor die. Specifically, a plurality of semiconductor dies 204 (such as core memory dies) can be stacked above an IF die 202. In this example, NCF material 210 can be disposed between adjacent semiconductor dies 204. Further, the NCF material 210 can be disposed between the IF die 202 and a lowest semiconductor die of the plurality of semiconductor dies 204. Here, the NCF material 210 can be pre-deposited on semiconductor wafers and singulated together with each one of the plurality of semiconductor dies 204. The NCF material 210 is applied here to provide mechanical support and to enhance the adhesion between semiconductor dies 204 and IF die 202. Each one of the semiconductor dies 204 may include multiple through silicon vias (TSVs) 214. In addition, the semiconductor dies 204 are bonded to the IF die 202 through contact pads 206 that are disposed on backside surface and frontside surface of corresponding semiconductor dies 204. The contact pads 206 are electrically connected through corresponding solder balls 208, and further coupled to corresponding TSVs of the semiconductor dies 204 for electrical interconnection. In this example, the NCF material can be made of low viscosity epoxy materials such as epoxy resins that have a thin and runny consistency. In some other examples, the semiconductor device assembly 200 may include a silicon substrate on which the plurality of semiconductor dies 204 are stacked. The semiconductor device assembly 200 can be encapsulated by packaging encapsulating material 212 for mechanical protection and enhancing overall reliability and performance of the semiconductor device assembly 200.

In this example, epoxy material can be introduced into the semiconductor device assembly 200 to regulate the profile and coverage of NCF material 210. For example, an epoxy layer 220 can be deposited on one or more sidewalls of the stacked semiconductor dies 204. As shown in FIG. 2, the epoxy layer 220 can extend from the backside surface of the IF die 202 to the most top semiconductor die of the plurality of semiconductor dies 204. More specifically, the epoxy layer 220 may only exist in a center region of each sidewall of stacked semiconductor dies 204. The epoxy layer 220 can be further encapsulated by the packaging encapsulating material 212.

The epoxy layer 220 can be cured at a lower temperature (e.g., up to 60° C.), in comparison to curing temperature of the NCF material 210, to maintain certain mechanical strength and be adhered on sidewalls of the stack of plurality of semiconductor dies 204. In particular, the epoxy layer 220 can be adhesive to silicon cores of the semiconductor dies 204. Moreover, the epoxy layer 220 may have similar material composition to the NCF material 210 and be adhesive to the NCF material 210 at the sidewall of the stack of plurality of semiconductor dies 204. In this example, the epoxy layer 220 may comprise epoxy-based materials, acrylic-based materials, polyimide-based materials, thermal curable polyimide, and/or UV curable polyacrylate materials.

In the cross section surface of the semiconductor device assembly 200 illustrated in FIG. 2, the epoxy layer 220 covers sidewall of NCF material 210 and prevents horizontally squeezing of the NCF material 210 out of the stacked semiconductor dies 204. In this example, the epoxy layer 220 may have a thickness ranging from 1 μm to 100 μm and a height ranging from 30 μm to 800 μm. Further, the epoxy layer 220 may comprise multiple layers of epoxy material proceeded by a repeated cycles of epoxy layer deposition process. The individual layer of the epoxy layer 220 may have a thickness ranging from 1 μm to 10 μm.

In some examples, the epoxy material may not cover certain regions of the stacked semiconductor dies 204 sidewalls. For example, the epoxy layer 220 may only exist at center regions of stacked semiconductor dies 204 sidewalls. With this configuration, NCF material 210 can extend, during a TCB process which applies heat and pressure, outside the corner regions of the semiconductor device assembly 200. The squeezing of NCF material 210 at corner regions may help prevent the NCF non-coverage issue or reduced thickness issue at corner areas of the semiconductor device assembly 200, therefore improving its overall reliability performance.

In this example, the semiconductor device assembly 200 can be a four-high (4H) HBM device including one top memory die and three core memory dies. In another example, the semiconductor device assembly 200 can be an eight-high (8H) HBM device including one top memory die and seven core memory dies. In another example, the semiconductor device assembly 200 can be a sixteen-high (16H) HBM device including one top memory die and fifteen core memory dies. In another example, the semiconductor device assembly 200 can be a thirty two-high (32H) HBM device including one top memory die and thirty one core memory dies. In some other examples, the semiconductor device assembly 200 can include multiple stacks of semiconductor dies that are bonded on a logic die. Each one of the multiple semiconductor die stacks can have epoxy material applied on its sidewalls to control the profile and flow of NCF materials.

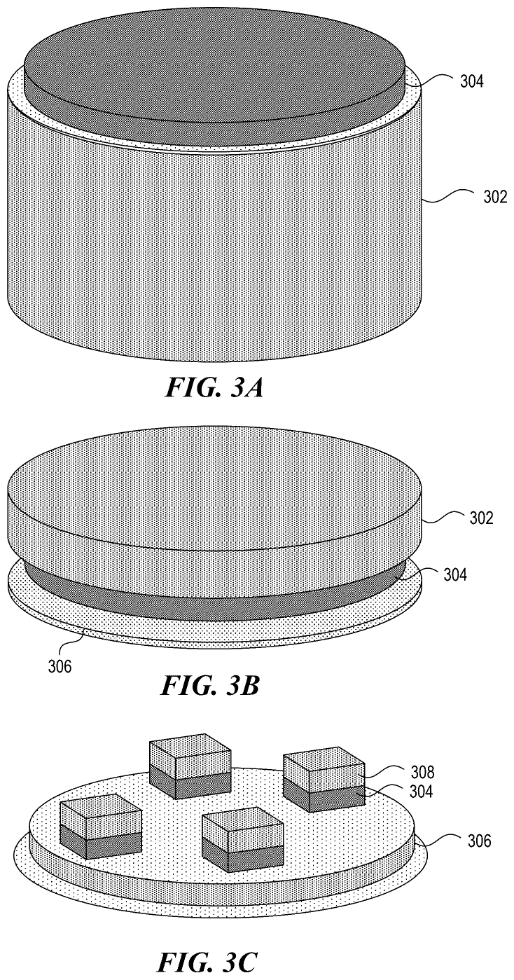

Beginning with FIG. 3A, a plurality of semiconductor dies (e.g., the plurality of semiconductor dies 204 of FIG. 2) can be provided for the semiconductor device assembly. In particular, FIGS. 3A through 3C illustrate stages of forming semiconductor dies for semiconductor device assembly in accordance with embodiments of the present technology. For example, as shown in FIG. 3A, a layer of NCF material 304 can be laminated on a frontside surface of a semiconductor wafer 302. The semiconductor wafer 302 can be a memory wafer and contains a plurality of memory dies. The NCF material can be evenly coated on the semiconductor wafer 302 using a spin coating technique or a dispensing equipment. A thermal treatment process may be performed to quickly cure the NCF layer above the semiconductor wafer 302. In this example, the plurality of memory dies disposed in the semiconductor wafer 320 may each include multiple TSVs.

Turning to FIG. 3B, the semiconductor wafer 302 and the NCF layer 304 can be adhered to a back grinding tape 306. Here, the semiconductor wafer 302 may be adhered to the back grinding tape 306 in a face down position so that the back side of the semiconductor wafer 302 is exposed for thinning. In this example, the back side of the semiconductor wafer 302 can be thinned through any appropriate method, for example, using back grinding, chemical-mechanical planarization (CMP), or the like. In aspects, the back grinding process may expose TSVs at the back side of the semiconductor wafer 302. After thinning, the back grinding tape 306 can be removed from the semiconductor wafers 302 and NCF layer 304 to enable the semiconductor wafer 302 to be diced.

As shown in FIG. 3C, the semiconductor wafer 302 and NCF layer 304 disposed there above can be diced into multiple semiconductor dies 308. Each one of the multiple semiconductor dies 308 has a NCF layer 304 coated on its frontside surface. Once diced, the multiple semiconductor dies 308 may be singulated from one another. The multiple semiconductor dies 308 can be further tested and assembled into packages. Specifically, the diced semiconductor dies 308 can be used in the HBM device packaging, e.g., as the plurality of memory core dies 204 in the semiconductor device assembly 200 shown in FIG. 2.

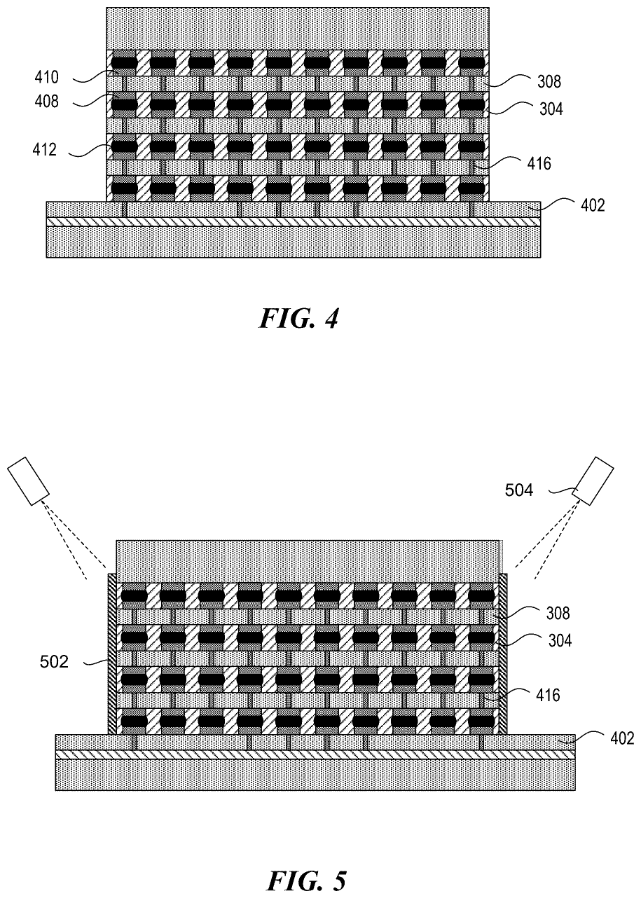

FIGS. 4 through 8 illustrate stages of forming semiconductor device assembly 800 in accordance with embodiments of the present technology. The fabrication of the semiconductor device assembly 400 starts from providing a semiconductor wafer 402. The semiconductor wafer can be an IF wafer that may include different types of semiconductor dies (e.g., logic dies, controller dies) than the plurality of semiconductor die stacks included in FIG. 2 (e.g., memory dies, DRAM products). The logic dies of the semiconductor wafer 402 can be configured to exchange electrical signals with the semiconductor dies bonded thereon and with higher level circuitry (e.g., a host device external to the semiconductor device assembly) coupled with the logic dies. In some embodiments, the semiconductor wafer 402 includes interposer dies having various conductive structures (e.g., redistribution layers, vias, interconnects) configured to route electrical signals between the plurality of semiconductor die stacks and higher-level circuitry e.g., a central processing unit (CPU) coupled with the semiconductor die stacks through the interposer die included in the Semiconductor wafer 402. In this example, the semiconductor wafer 402 can be placed frontside down for the downstream hybrid semiconductor dies stacking processes. In another example, the semiconductor wafer 402 may also include contact pads on its backside surface. In some other examples, the semiconductor wafer 402 can be a silicon wafer.

In this stage, a plurality of semiconductor dies 308 can be bonded on the semiconductor wafer 402. In particular, the plurality of semiconductor dies 308 can be stacked through bonding of contact pads 408, 410, and solder balls 412 disposed there between. In this CoW bonding scheme, the plurality of semiconductor dies 308 can be bonded using the TCB technique on the back side surface of the semiconductor wafer 402 through the application of heat and pressure there between. Specifically, the contact pads of the lowest semiconductor die 308 in the semiconductor die stack can be aligned to and bonded to corresponding contact pads of the semiconductor wafer 402. The plurality of semiconductor dies 308 can be memory dies fabricated in the flow described in FIGS. 3A to 3C. Each one of the semiconductor dies 308 can be a memory core die having a layer 304 of NCF material on its frontside surface. The NCF layer 304 underfills gaps of adjacent semiconductor dies 308 and provides adhesion as well as mechanical support. In this stage, four semiconductor dies 308 can be stacked on the semiconductor wafer 402, targeting a 4H HBM device assembly shown on the end of the flow. The NCF layer 304 may be made of epoxy-based materials such as low viscosity epoxy material, acrylic-based materials, and/or polyimide-based materials.

Turning to a next stage shown on FIG. 5 in which epoxy material can be applied on the semiconductor device assembly. Specifically, epoxy layers 502 can be deposited on sidewalls of the stacked plurality of semiconductor dies 308. In some examples, the epoxy layers 502 can be deposited by a 3D printing technology. An inkjet printer system having multiple nozzles can be adopted to deposit thermal-cure polyimide (PI) and/or UV-cure polyacrylate (PA) materials as the epoxy layers 502 for the semiconductor device assembly. The inkjet printer system may include up to hundreds of nozzles 504 for delivering the epoxy material and guiding the growth of epoxy layers 502. In this example, multiple epoxy layers 502 can be deposited simultaneously or sequentially. As shown in FIG. 5, the epoxy layers 502 can extend from a backside surface of the Semiconductor wafer 402 to the most top semiconductor die 308. Multiple cycles of epoxy deposition can be conducted to achieve a target epoxy layer thickness, e.g., ranging from 1 μm to 100 μm. The nozzles 504 can move along the vertical direction and/or adjust its injecting angle towards the sidewall of stacked semiconductor dies 308. The height of the epoxy layers 502 may range from 30 μm to 800 μm. In some other examples, the thickness and height of the epoxy layers 502 may vary depending on the semiconductor die design and packaging criteria, not limited by the printing process. Further, the nozzle temperature and sizes can be adjusted to achieve various profiles of the epoxy layers 502.

In this example, the epoxy layers 502 can be applied at a center region of each sidewall of stacked semiconductor dies 308. Specifically, the epoxy layers 502 can be configured as barrier layers to stop diffusion of NCF material outside the regions of stacked semiconductor dies 308 during the TCB bonding process. Furthermore, to prevent NCF non-coverage at corner of semiconductor device packages, the NCF material can be pushed (e.g., by the heat and pressure applied in the TCB process) outside the packaging region of semiconductor dies 308 where no epoxy material exists (e.g., the corner regions).

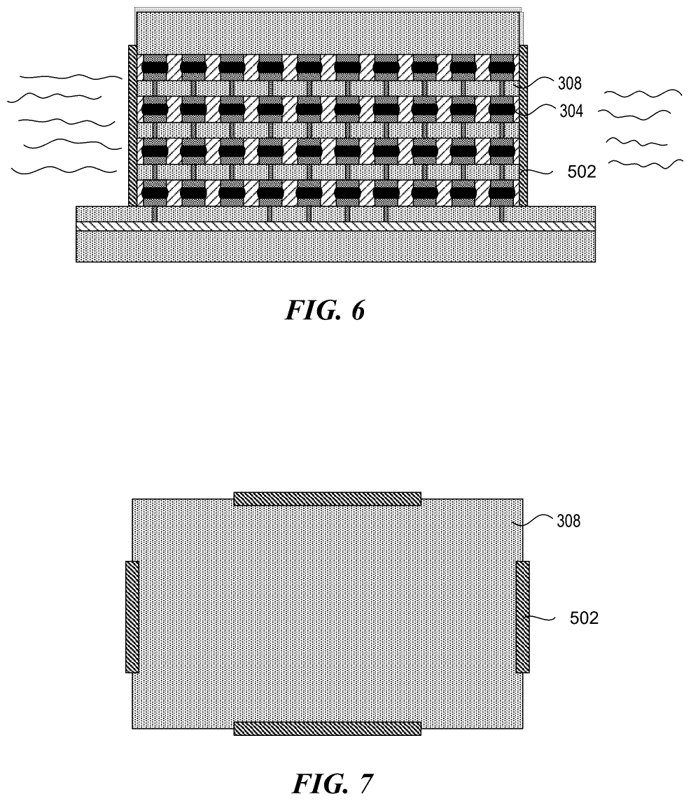

The epoxy layers 502 can be cured at a lower temperature (e.g., up to 60° C.), in comparison to curing temperature of the NCF material 210, to solidify the epoxy layers 502 on sidewalls of the stack of plurality of semiconductor dies 308. FIG. 6 illustrates a stage of curing treatment on deposited epoxy material of semiconductor device assembly in accordance with embodiments of the present technology. In this stage, the as deposited epoxy layers 502 can be cured by various techniques. For example, an ultraviolet (UV) curing process can be implemented to quickly and efficiently cure the epoxy layers 502. This UV curing process can use UV light to initiate a photochemical reaction that rapidly hardens or cures the epoxy material. The UV curing process can be incorporated with UV curable polyacrylate materials as the epoxy layers 502 in this example. In another example, thermal cure polyimide can be adopted as the epoxy material for the epoxy layers 502. Accordingly, a thermal curing process can be conducted in this stage. For example, thermal curing can be conducted by relying on elevated temperatures to trigger chemical reactions that lead to hardening or cross-linking of polyimide materials.

The working temperature of the above describe curing process can be equal to or lower than 60° C., so that the epoxy layers 502 can be UV cured or thermal cured after dispensing without curing the NCF between the semiconductor dies 308 prior to the collective bonding process. The candidate epoxy materials described above have different tensile modulus that could be selected based on performance in the semiconductor device assembly. The epoxy materials applied here are used in semiconductor applications and have the ability to adhere to silicon. In particular, the epoxy layers 502 can be adhesive to silicon cores of the semiconductor dies 308. Moreover, the epoxy layers 502 can have similar material compositions to the NCF material 304 and adhere to the NCF material 304 at the sidewall of the stack of plurality of semiconductor dies 308. In this example, the epoxy layers 502 may comprise epoxy-based materials, acrylic-based materials, polyimide-based materials, thermal curable polyimide, and/or UV curable polyacrylate materials.

FIG. 7 shows a top-down view of the semiconductor device assembly after epoxy curing in accordance with embodiments of the present technology. As discussed, the epoxy layers 502 can be deposited and hardened along a center region of each sidewalls of the stacked plurality of semiconductor dies 308. In accordance with the semiconductor device design and packaging requirements, the location and length of each of the epoxy layers 502 can be varied.

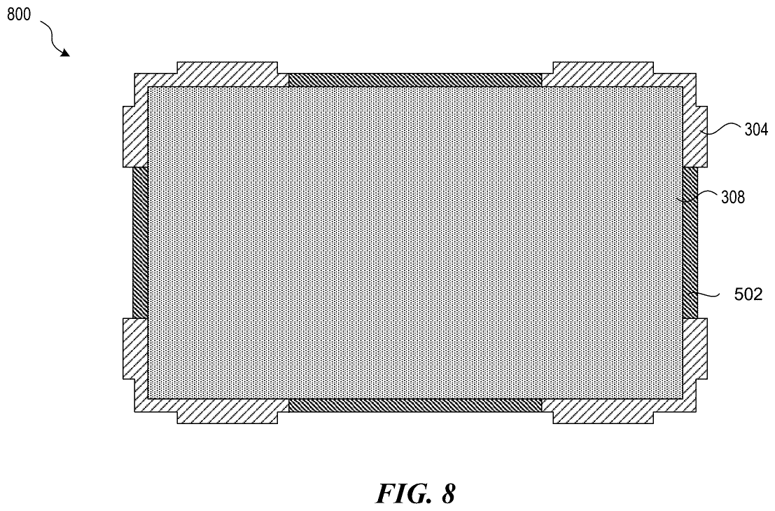

In the next stage, a TCB process can be performed again to apply heat and pressure on the semiconductor device assembly 800. Here, the solder bumps or paste on the contact pads begin to melt due to the heat and form liquid solder. The combined effect of heat and pressure causes the metallic materials (e.g., contact pads 408, 410) and solder balls 412 on the pads to reflow, to form the interconnections, bond line thickness, and NCF fillet. Meanwhile, the applied heat soften the NCF material 304 and make it conductive, facilitating the formation of electrical interconnections between the contact pads 408 and 410 of adjacent semiconductor dies 308. In addition, the applied pressure may push the softened NCF material 304 squeeze out of the stack of semiconductor dies 308. For example, FIG. 8 illustrates a stage of NCF material extending outside the semiconductor dies of the semiconductor device assembly 800 in accordance with embodiments of the present technology. In particular, the NCF material 304 squeezes out of the corner regions of stacked semiconductor dies 308. In comparison, no NCF material extends across the epoxy layers 502. In this example, the NCF material 304 can flow through entire gaps between adjacent semiconductor dies 308 so as to reduce or prevent the non-NCF material coverage defects.

The present technology utilizes epoxy layers 502, as described above, to prohibit NCF material 304 from extending across center regions of side walls of semiconductor die 308. This configuration can prevent bridging of NCF material between parallel sidewalls of adjacent stack of semiconductor dies in the CoW packaging, therefore avoiding higher or abnormal wafer or semiconductor die warpages post the TCB process. It can help reduce the impacts from increased BLT around the perimeter of the package due to die warpage which can cause open interconnects and reliability concerns. In addition, the control of NCF material extending at center regions of sidewalls can reduce flammability concerns on some NCF materials. Further, the epoxy layers 502 disposed on sidewalls of stacked semiconductor dies 308 can prevent striping in the encapsulation due to the exposed NCF material, which may not be appealing to customers. In some examples, the application of epoxy layers 502 can allow thicker NCF material to be disposed between adjacent semiconductor dies, in order to reduce NCF void risk inside the semiconductor package. Moreover, the reduction of NCF material squeezing between paralleled sidewalls of adjacent stacks of semiconductor dies can allow an enhanced semiconductor device packaging density through reducing the space between adjacent stacks of semiconductor dies. In some other example, the NCF material 304 may only squeeze out of one or more corner regions of the stack semiconductor dies 308.

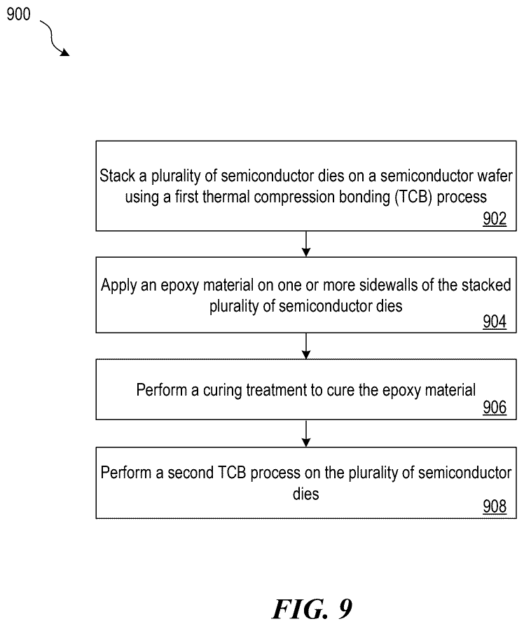

Turning now to FIG. 9 which is a flow chart illustrating a method 900 of processing semiconductor device assemblies with epoxy material dispose on sidewalls in accordance with embodiments of the present technology. The method 900 includes stacking a plurality of semiconductor dies on a semiconductor wafer using a first TCB process, wherein a NCF material is disposed between adjacent semiconductor dies of the plurality of semiconductor dies and the semiconductor wafer, at 902. For example, the plurality of semiconductor dies 308 can be bonded on the semiconductor wafer 402, as shown in FIG. 4. Each of the semiconductor dies 308 may have a NCF material layer deposited on its frontside surface. The plurality of semiconductor dies 308 can be collectively bonded to each other and to the semiconductor wafer 402. Here, the first TCB process is adopted to use a lower temperature process to mainly get the plurality of semiconductor dies 308 to stick to each other.

The method 900 also includes applying an epoxy material on one or more sidewalls of the stacked plurality of semiconductor dies, at 904. For example, epoxy layers 502 can be coated on a center region of sidewalls of stacked semiconductor dies 308. As described in FIG. 5, a 3D printing technique can be adopted to deposit the epoxy layers 502 from the backside surface of the semiconductor wafer 402 to the most top semiconductor die of the plurality of semiconductor dies 308. The epoxy layers 502 can be adhered to the semiconductor dies 308 and/or the NCF material 304.

In addition, the method 900 includes performing a curing treatment to cure the epoxy material, at 906. For example, a UV cure process or a low temperature thermal treatment process can be conducted to harden the as deposited epoxy layers 502. The working temperature for the UV cure process or low temperature thermal treatment process should be equal to or lower than 60° C., to avoid impacting the NCF material 304 which has a higher curing temperature.

Lastly, the method 900 includes performing a second TCB or mass reflow process on the plurality of semiconductor dies, at 908. For example, after the epoxy layers 502 are cured, the TCB process can be applied again on the semiconductor device assembly 800. As discussed in FIG. 8, the heat and pressure applied in the TCB process can cause the contact pads 408, 410, and solder balls 412 to reflow, causing the interconnections to melt and mix together. Meanwhile, the applied heat causes NCF material 304 to soften and become conductive, facilitating the formation of electrical interconnections between the contact pads 408 and 410 of adjacent semiconductor dies 308. Further, the applied pressure may push the softened NCF material 304 squeezing out of the stack of semiconductor dies 308.

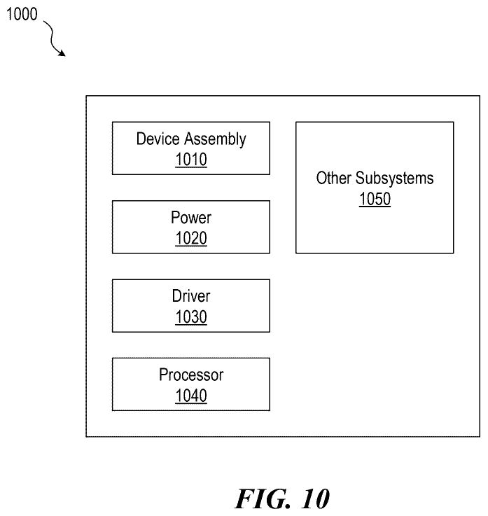

Any one of the semiconductor structures described above with reference to FIGS. 2 to 9 can be incorporated into any of a myriad of larger and/or more complex systems, a representative example of which is system 1000 shown schematically in FIG. 10. The system 1000 can include a semiconductor device assembly 1010, a power source 1020, a driver 1030, a processor 1040, and/or other subsystems or components 1050. The semiconductor device assembly 1010 can include features generally similar to those of the semiconductor device assemblies described above, and can therefore include the epoxy material disposed on sidewalls of stacked semiconductor dies described in the present technology. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, and appliances. Components of the system 1000 may be housed in a single unit or distributed over multiple, interconnected units (e.g., through a communications network). The components of the system 1000 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a lower semiconductor die;
a stack of upper semiconductor dies disposed over the lower semiconductor die;
a non-conductive film (NCF) material disposed between adjacent semiconductor dies of the lower semiconductor die and the stack of upper semiconductor dies; and
an epoxy material disposed on at least one sidewall of the stack of upper semiconductor dies, wherein the epoxy material has a different material composition to the NCF material.

2. The semiconductor device of claim 1, wherein the epoxy material extends from a backside surface of the lower semiconductor die to a sidewall of a most top semiconductor die of the stack of upper semiconductor dies.

3. The semiconductor device of claim 1, wherein the epoxy material is disposed at center region of each sidewall of the stack of upper semiconductor dies.

4. The semiconductor device of claim 3, wherein the epoxy material is configured to perform as a barrier layer to stop the NCF material from squeezing out of the stack of upper semiconductor dies.

5. The semiconductor device of claim 4, wherein the NCF material squeezes out the stack of upper semiconductor dies at regions of sidewalls of the stack of upper semiconductor dies which is not covered by the epoxy material.

6. The semiconductor device of claim 1, wherein the epoxy material disposed on at least one sidewall of the stack of upper semiconductor dies has a height ranging from 30 μm to 800 μm and a thickness ranging from 1 μm to 100 μm.

7. The semiconductor device of claim 1, wherein the epoxy material included multiple layers, each layer having a thickness ranging from 1 μm to 30 μm.

8. The semiconductor device of claim 1, wherein the epoxy material is adhesive to the stack of upper semiconductor dies and/or the NCF material.

9. The semiconductor device of claim 1, wherein the epoxy material has a curing temperature lower than that of the NCF material, and wherein the curing temperature of the epoxy material is up to 60° C.

10. The semiconductor device of claim 1, wherein the epoxy material comprises epoxy-based materials, acrylic-based materials, polyimide-based materials, thermal curable polyimide, and/or ultraviolet (UV) curable polyacrylate materials.

11. A semiconductor device, comprising:
a plurality of semiconductor dies that are vertically stacked on an interposer die;
a non-conductive film (NCF) material disposed between adjacent dies of the plurality of semiconductor dies and the interposer die; and
an epoxy material disposed at center region of sidewalls of the plurality of semiconductor dies, wherein the epoxy material is configured to prevent the NCF material from squeezing out of the sidewalls of the plurality of semiconductor dies.

12. The semiconductor device of claim 11, wherein the NCF material squeezes out corner regions of the plurality of semiconductor dies.

13. The semiconductor device of claim 11, wherein the epoxy material squeezes out of a backside surface of the interposer die to a sidewall of a most top semiconductor die of the plurality of semiconductor dies.

14. The semiconductor device of claim 11, wherein the epoxy material has a different material composition to the NCF material, and wherein the epoxy material has a curing temperature lower than that of the NCF material.

15. A method of forming a semiconductor device, comprising:
stacking a plurality of semiconductor dies on a semiconductor wafer using a first thermal compression bonding (TCB) process, wherein a non-conductive film (NCF) material is disposed between adjacent semiconductor dies of the plurality of semiconductor dies and the semiconductor wafer;
applying an epoxy material on one or more sidewalls of the stacked plurality of semiconductor dies;
performing a curing treatment to cure the epoxy material; and
performing a second TCB process on the plurality of semiconductor dies.

16. The method of claim 15, wherein applying the epoxy material includes vertically depositing the epoxy material from a backside surface of the semiconductor wafer to a most top semiconductor die of the plurality of semiconductor dies.

17. The method of claim 15, wherein the epoxy material is applied at a center region of sidewalls of the plurality of semiconductor dies, wherein the epoxy material is configured to prevent the NCF material from squeezing out of the sidewalls of the plurality of semiconductor dies, and wherein the NCF material squeezes out of corner regions of the plurality of semiconductor dies.

18. The method of claim 15, wherein the curing treatment is an ultraviolet (UV) cure process or a low temperature thermal treatment process, the curing treatment being conducted at a temperature lower than that of the second TCB process, and wherein the epoxy material can be cured at a temperature up to 60° C.

19. The method of claim 15, wherein the epoxy material can be applied using a 3D printing technique and through multiple nozzles, and wherein the epoxy material can be formed by repeated cycles of epoxy layer deposition, each epoxy layer having a thickness ranging from 1 μm to 30 μm.

20. The method of claim 15, wherein the epoxy material is adhesive to the plurality of semiconductor dies and/or the NCF material.
